(19) United States
(12) Patent Application Publication
(10) Pub. No.: US 2002/0070445 A1
(43) Pub. Date: Jun. 13, 2002

(54) Enveloped thermal interface with metal matrix components

(75) Inventor: Thomas S. Tarter, San Jose, CA (US)

Correspondence Address: McDERMOTT, WILL & EMERY, 600 13th Street, N.W., Washington, DC, 20005-3096, US

(73) Assignee: Advanced Micro Devices, Inc.

(21) Appl. No.: 09/734,552

(22) Filed: Dec. 13, 2000

Related U.S. Application Data
(60) Provisional application No. 60/215,097, filed on Jun. 29, 2000.

(51) Int. Cl. H01L 23/42

(52) U.S. Cl. 257/714; 438/122

(57) ABSTRACT

An enveloped thermal interface servers as a heat-conducting spacer between a heat dissipating member and an electronic package or device. Embodiments of the present invention include a member comprising a hermetically sealed thermal interface. A conformable metallic envelope containing a heat-conducting matrix, such as a eutectic alloy having a melting point below the normal operating temperature of the packaged device.

### RELATED APPLICATION

This application claims priority from Provisional Application Serial No. 60/215,097 filed on Jun. 29, 2000 entitled: “ENVELOPED THERMAL INTERFACE WITH METAL MATRIX COMPONENTS”, the entire disclosure of which is hereby incorporated by reference herein.

### FIELD OF THE INVENTION

The present invention relates to a semiconductor package comprising a heat sink, and in particular, to a thermal interface disposed between the heat sink and a semiconductor chip or package.

### BACKGROUND OF THE INVENTION

For proper power dissipation in an integrated chip (IC), it is necessary to draw heat away from a semiconductor die, and to dissipate the heat in an efficient manner to prevent excessive temperature build-up and to minimize possible adverse effects, such as dimensional variations, differential thermal expansion, and the like. Heat is generally transferred from the die to a heat diffuser, a heat sink, or to a cooling device. Consequently, thermal resistance at the interface between the die surface and the heat diffuser should be minimal, and interfacial contact between the die surface and the heat diffuser should be maximal in order to maximize heat dissipation.

Typically, a metallic heat sink is mechanically attached to a die or dice using thermoconductive films, adhesives, or materials with thermally conductive fillers, such as greases, gels, pastes, thermoset resins, or pads. While these materials are satisfactory for some applications, they continue to suffer from a number of drawbacks.

For example, greases are difficult to handle during application, and tend to attract particulates from the atmosphere causing contamination and accumulations on the device surface, thereby adversely affecting thermal conductivity. Moreover, greases tend to migrate to adjacent spaces over time and generally exhibit a mediocre thermal conductivity, e.g., about 1.8 Watt/m-K, which is disadvantageously reduced as the thickness of a grease layer increases.

Thermal conductive films are non-conforming and cannot serve as an effective thermal interface between even surfaces of a multi-chip module and a heat sink. For use on uneven surfaces, compliant thermal conductive pads acting as a spacer have been devised. However, known pads are made of a silicone-composition characterized by limited compliancy. Heat conductive filler pads exhibit an undesirably low thermal conductivity K of 0.8 W/m-K to 1.5 W/m-K.

Advancing to FIG. 1, a conventional heat conductive adhesive film 12 is positioned between a cooling film 10 and a semiconductor die 14 which is soldered to a package board 16.

The thermal conductivity of thermoset resins with conductive fillers ranges from 2.2 to 4 Watt/m-K, depending on the particular type of filler used. However, thermoset resins disadvantageously require additional processing steps, e.g., curing after application on an electrical device. In addition, thermoset processing tends to impart high stress on the components it is attached to, and adhesion to various surfaces is required.

Accordingly, there exists a need for a highly efficient thermally conductive interface/spacer that can be easily handled while providing maximal heat transfer from a semiconductor die to a heat-dissipating member transfer for cooling fast and high-powered integrated circuit chips. Such efficient thermal interface material should desirably have a thermal conductivity value, K, of greater than about 50 W/mK, e.g., about 50 to about 120 W/mK, and possess substantial flexibility to provide maximum surface contacts by conforming to surfaces of varying heights.

### BRIEF DESCRIPTION OF THE DRAWINGS

Reference is made to the attached drawings, wherein elements having the same reference numeral designations represent like elements throughout, and wherein:

FIG. 1 schematically illustrates a prior art use of thermal conductive film or pad;

FIG. 2 schematically shows a cross-sectional view of an embodiment of the present invention;

FIG. 3A schematically illustrates an explode-view of the embodiment of FIG. 2;

FIG. 3B schematically illustrates another embodiment of the present invention having a single metal sheet forming an envelope containing a thermal conductive matrix;

FIG. 4 schematically illustrates an embodiment of the invention;

FIG. 5 schematically illustrates an embodiment of the invention comprising a multi-chip package arrangement.

### SUMMARY OF THE INVENTION

The present invention relates to an enveloped thermal interface comprising a flexible and hermetically sealed metallic envelope having a thermal conductive matrix disposed therein. Embodiments of the invention comprise a thermally conductive spacer for interfacing a multi-chip module with a heat-dissipating member, wherein the spacer includes a flexible, conformable and substantially flat metallic container containing the heat-conducting matrix comprised of a eutectic alloy having a melting point below the normal operating temperature of the semiconductor dice on the multi-chip module.

Another aspect of the present invention is an integrated circuit package arrangement, including a semiconductor die, a package substrate for holding the semiconductor die, an enveloped thermal interface disposed on top the semiconductor die, and a heat sink disposed on top of the thermal interface envelope, wherein the thermal interface envelope is flat, flexible, metallic and contains a thermal conductive matrix of a eutectic alloy.

A further aspect of the present invention is a method for producing a thermally conductive spacer, the method comprising forming a substantially flat container from a flexible metal, filling the container with a heat-conducting matrix, hermetically sealing the container, and applying a layer of electrical insulating film on an outer surface of the container.

The present invention provides significant advantages over prior art devices and methods. For example, the present invention comprises an enveloped thermal interface having a high thermal conductivity, e.g., above 50 Watt/mK, easy to manipulate, thereby facilitating integration in existing fabrication facilities without contaminating components or equipment. Embodiments of the present invention include envelopes exhibiting sufficient flexibility and conformability thereby advantageously maximizing thermal interface contact between a heat-dissipating member and multiple dice of different heights.

Additional advantages of the present invention will become readily apparent to those skilled in this art from the following detailed description, wherein only the preferred embodiment of the present invention is shown and described, simply by way of illustration of the best mode contemplated for carrying out the present invention. As will be realized, the present invention is capable of other and different embodiments, and its several details are capable of modifications in various obvious respects, all without departing from the present invention. Accordingly, the drawings and description are to be regarded as illustrative in nature, and not as restrictive.

### DETAILED DESCRIPTION OF THE INVENTION

This present invention addresses and solves problems related to the cooling of semiconductor die which generate heat during their operation. More particularly, the present invention relates to an enveloped thermal interface that also serves as a heat-conducting spacer between a heat dissipating member and one or more semiconductor dice disposed on a package board. Thermal interfaces utilizing thermal-conductive materials that are non-metallic with metallic fillers are more efficient than conventional thermal interfaces in accordance with embodiments of the present invention.

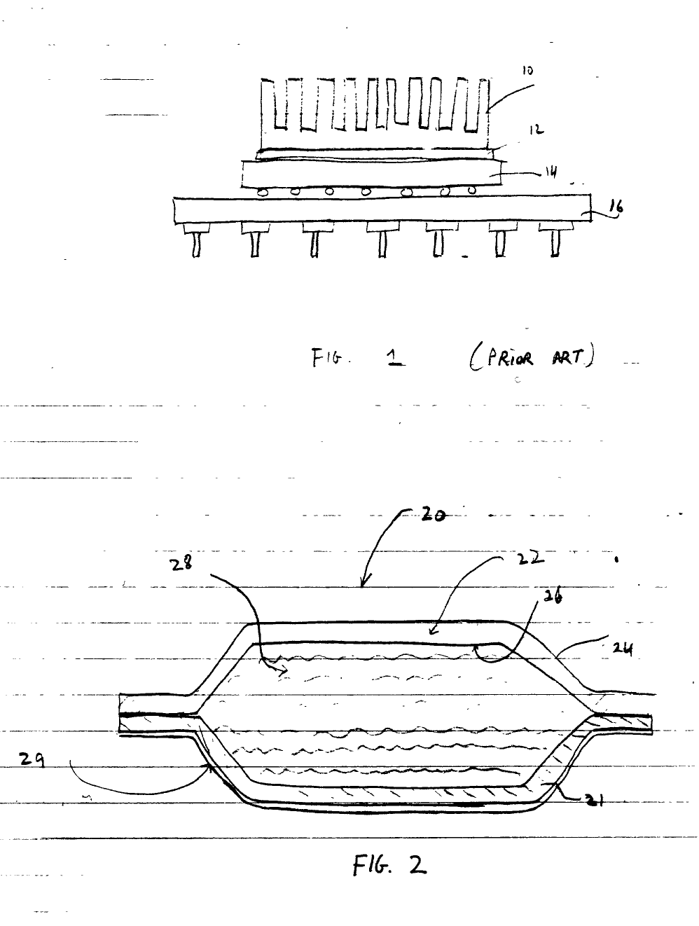

An embodiment of the present invention is schematically illustrated in FIG. 2 and comprises enveloped thermal interface 20 in the form of a container made of a flexible and highly thermal conductive metal, such as aluminum, steel, copper, brass, tin and the like. The illustrated container includes two sheets of metal 21 and 22. The thickness of the metal sheet is in the range of about 1 to about 5 mils, such as about 1 to about 3 mils thick, e.g., about 1 to about 2 mils thick. The two sheets are joined together, as by welding, rolling, press-fitting, or adhering, by any means, to form the container in which a thermally conductive matrix is disposed and hermetically sealed. The sheets can also be joined by other conventional technologies, such as brazing or ultrasonic bonding.

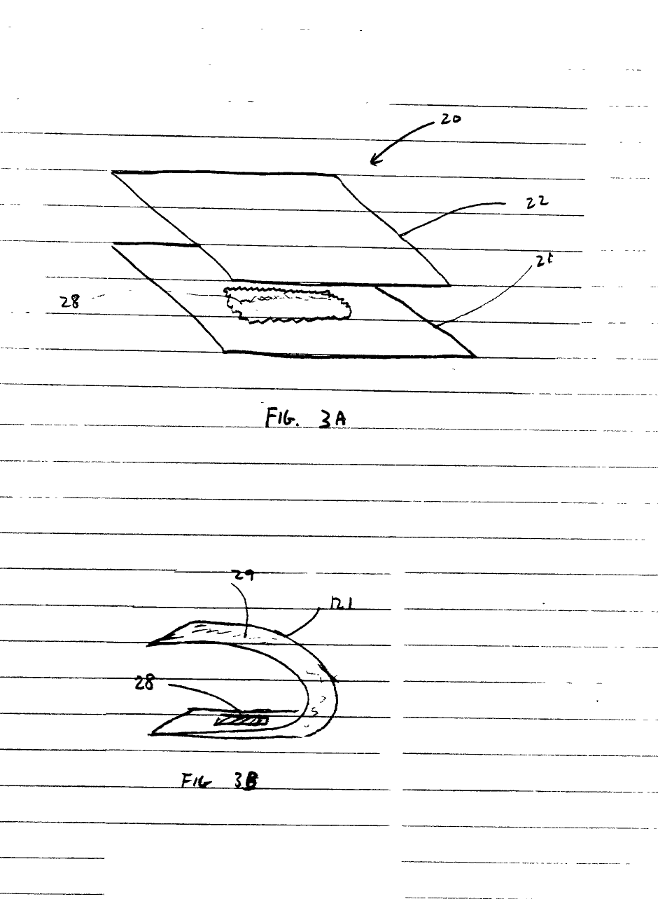

The container has an exterior surface 24 and an interior surface 26. The entire exterior surface 26 can be coated with an electrical insulating film 29. An exploded view of the enveloped thermal interface 20 of FIG. 2 is illustrated in FIG. 3A. In another embodiment of the present invention, exterior surface 26 is coated only on the portion that makes contact with a semiconductor die. Such an electrically insulating coating prevents the metallic container from shorting the circuitry on the semiconductor die. The coating can comprise a durable, electrically non-conductive material, and can be applied to the metal sheet before or after forming the container. A suitable electrically insulating coating material is mylar. Further, the electrical insulating film may also be colorized so that the uncoated portion can be easily distinguished from the uncoated portion.

Referring now to FIG. 3B, another embodiment of the present invention comprises an enveloped thermal interface 20 including the thermal conductive matrix 28 disposed on a single sheet of metal 121. The single sheet of metal 121 is folded and hermetically sealed to form an envelope enclosing the matrix. In this embodiment, an electrically insulting film is also disposed on the exterior of the envelope. If the electrically insulating film is coated on the metal sheet prior to forming the envelope, the sheet would be folded in a manner in which the insulating film is on the exterior surface of the envelope. The entire enveloped thermal interface formed, including the metal sheet and the thermally conductive matrix as shown in FIGS. 3A and 3B, typically has a thickness of about 2 mils to about 20 mils, such as about 3 to about 15 mils, e.g., about 5 mils to about 10 mils.

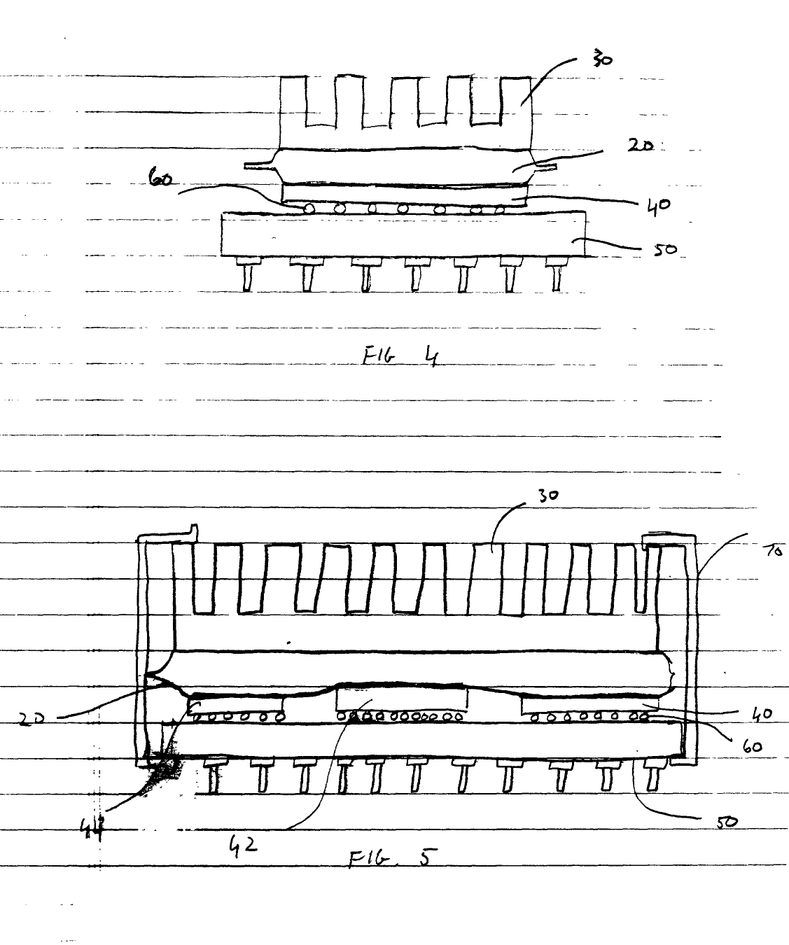

In another embodiment of the present invention, an enveloped thermal interface 20, as shown in FIG. 4, is positioned between a cooling fin 30 and a semiconductor die 40. The semiconductor die 40 is joined to a package board 50 with reflowed solder bumps 60. The enveloped thermal interface 20 has a surface area that is substantially equivalent to that of the semiconductor die.

In another embodiment of the present invention, an enveloped thermal interface 20, as shown in FIG. 5, is disposed between a cooling fin 30 and semiconductor dice 40, 42, and 44, which are joined to a package board 50. The interface 20 has a dimension that is sufficiently large to cover the semiconductor dice.

In order to maximize thermal transfer from the dice to the cooling fin, an adhesive is not used with the enveloped thermal interface 20, thereby avoiding a reduction in the thermal transfer efficiency of the enveloped thermal interface. Instead, in accordance with embodiments of the present invention, the cooling fin 30 and the enveloped thermal interface are fastened to the package board by non-adhesive means, e.g., mechanical means such as a pair of clamps 70.

Embodiments of the present invention are not limited for use with the cooling fins shown in FIGS. 4 and 5. Other heat-dissipating members may be employed, such as a heat sink, a metal, a ceramic, a plastic casing, or an active cooling apparatus.

The semiconductor dice 40, 42, and 44 illustrated in FIG. 5 extend to different heights above the supporting surface of the package board. This difference in heights is due to the varying thickness of each semiconductor die and/or the varying clearance space between each die and the supporting surface of the package board. Advantageously, the enveloped thermal interfaces in accordance with embodiments of the present invention are flexible and compliant, thereby conforming to the irregular interface between the cooling fin and the semiconductor dice of varying heights. Such a conformal property of the enveloped thermal interface is enhanced as the thermally conductive matrix changes phase when semiconductor dice reach a normal operating temperature.

Embodiments of the present invention include a thermally conductive matrix comprising a eutectic alloy, such as a eutectic alloy in the form of a solid paste or liquid. A solid and pasty state matrix is very controllable and, therefore, convenient and useful when dispensed and enveloped by a metal sheet. The liquid state renders the thermal interface more flexible and conformable. Because the conductive matrix is contained in a metal envelope there is no migration of the matrix to other components to cause contamination or shorts. The phase change of the thermally conductive matrix is dependent upon its composition. The thermally conductive matrix of the present invention preferably has a melting point of about 60° C. and about 90 ° C. Below the melting point temperature, the matrix is in a solid, pasty state as mentioned.

Suitable euctectic alloys for use in embodiments of the present invention include bismuth alloys, tellurium alloys, indium alloys and gallium alloys. For example, a suitable bismuth alloy comprises about 5 to about 20% gallium, about 10 to about 15% tin, the remainder bismuth. The melting point of the matrix can be controlled by varying the composition of the eutectic alloy.

Euctectic alloys are relatively benign in terms of toxicity and exhibit excellent thermal conductivity. Moreover, as they are contained in a metal envelope, the matrix is safe and easy to handle, and enables formation of an excellent thermal interface as a package.

The above-described enveloped thermal interface is manufactured according to the following method, including the steps of forming a substantially flat container from a flexible metal, filling the container with a heat-conducting matrix comprising a eutectic alloy in a pasty state, and hermetically sealing the container by welding.

The present invention enjoys industrial utility in fabricating various types of semiconductor packages. The present invention enjoys particular industrial utility in fabricating semiconductor devices containing high speed, high power integrated circuit chips containing heat dissipating means.

Only the preferred embodiment of the present invention and but a few examples of its versatility are shown and described in the present disclosure. It is to be understood that the present invention is capable of use in various other combinations and environments and is capable of changes or modifications within the scope of the inventive concept as expressed herein.

What is claimed is:

1. A thermal interface for conducting heat generated by a semiconductor chip to a heat-dissipating member, the thermal interface comprising:
a flexible, hermetically sealed metallic envelope; and
a thermal conductive matrix disposed within the envelope.

2. The thermal interface according to claim 1, wherein the thermal conductive matrix has a melting point that is lower than operating temperature of the semiconductor chip.

3. The thermal interface according to claim 1, wherein the conductive matrix comprises a eutectic alloy.

4. The thermal interface recited in claim 3, wherein the alloy comprises the bismuth, tellurium, indium or gallium alloy.

5. The thermal interface according to claim 1, having a thermal conductivity greater than 50 Watt/meter-Kelvin.

6. The thermal interface according to claim 1, comprising an electrically insulating coating on an exterior surface of the envelope.

7. The thermal interface according to claim 6, wherein the electrically insulating coating is at least on a portion of the exterior surface of the envelope facing the heat generating semiconductor chip, wherein a portion of the exterior of the envelope that faces the heat generating source is coated with an electrical insulator.

8. A thermally conductive spacer for interfacing a multi-chip module with a heat-dissipating member, the spacer comprising:
a conformable metallic substantially flat container containing a heat-conducting matrix.

9. The thermally conductive spacer recited in claim 8, wherein the container comprises a first wall and a second wall, the first wall, facing the multi-chip module, is insulated with an electrically non-conductive film, and the second wall facing the heat-dissipating member.

10. The thermally conductive spacer of claim 8, wherein the container is hermetically sealed.

11. The thermally conductive spacer of claim 8, wherein the heat-conducting matrix is characterized by a melting point lower than a normal operating temperature of the multi-chip module.

12. The thermally conductive spacer of claim 8, wherein the heat-conducting matrix has a melting point in a range of 93° C. to 125° C.

13. The thermally conductive spacer of claim 8, wherein the heat-conducting matrix is a eutectic alloy from a group comprising bismuth, tellurium, gallium and indium.

14. A method of producing a thermally conductive spacer, the method comprising:
forming a substantially flat container from a flexible metal;
filling the container with a heat-conducting matrix; and
hermetically sealing the container.

15. The method according to claim 14, wherein the metal has an electrically insulating film on a surface thereof, the method comprising forming the container such that the electrically insulating film is on an exterior surface thereof.

16. The method according to claim 14, further comprising applying an electrically insulating film on an outer surface of the container.

17. The method according to claim 14, wherein the heat-conducting matrix comprises an eutectic alloy.

18. The method according claim 17, where the eutectic alloy comprises a bismuth, tellurium, indium or gallium alloy.

19. The method of according to claim 17, further comprising:

20. A integrated circuit package arrangement, comprising:
a package substrate having a semiconductor die mounted thereon,
a thermal interface disposed on top the semiconductor die or package; and
a heat sink disposed on top of the thermal interface, wherein the thermal interface is substantially flat, flexible, and comprises a metallic envelope containing a thermal conductive matrix.

21. An integrated circuit package arrangement according to claim 20, wherein the thermal conductive matrix comprises a euctectic alloy.

22. The semiconductor integrated circuit package arrangement according to claim 21, wherein the eutectic alloy comprises a bismuth, tellurium, indium or gallium alloy.
